(19) United States
(12) Patent Application Publication
(10) Pub. No.: US 2003/0062556 A1
(43) Pub. Date: Apr. 3, 2003

(54) Memory array employing integral isolation transistors

(76) Inventors: Hartmud Terletzki, Pleasant Valley, NY (US); Alfred Schuetz, Germering (DE); Selwyn Rhys Weaver, Poughkeepsie, NY (US)

Correspondence Address: LERNER, DAVID, LITTENBERG,, KRUMHOLZ & MENTLIK, 600 SOUTH AVENUE WEST, WESTFIELD, NJ, 07090, US

(21) Appl. No.: 09/967,007

(22) Filed: Sep. 28, 2001

(51) Int. Cl. H01L 29/76

(52) U.S. Cl. 257/296

(57) ABSTRACT

A memory, includes memory array disposed in an isolated well of semiconductor material and including a plurality of storage cells, each storage cell being accessible via one of a plurality of bit lines; a set of isolation transistors disposed in the isolated well of semiconductor material, each transistor having one of a source and drain coupled to a respective one of the bit lines of the memory array; and a sense amplifier disposed in semiconductor material outside the isolated well of semiconductor material and being coupled to the other of the source and drain of the respective isolation transistors.

### BACKGROUND OF THE INVENTION

The present invention relates to memory devices, including but not limited to dynamic random access memories (DRAMs) and, more particularly, to a memory array employing integral isolation transistors.

With reference to FIG. 1, a conventional memory 10 includes a first memory array 12, a second memory array 14, a sense amplifier 16, a first set of isolation transistors 18, and a second set of isolation transistors 20.

Each of the first and second memory arrays 12, 14 include a plurality of storage cells arranged in an array. FIG. 2 is a schematic diagram of a conventional array of storage cells 22. Each storage cell 22 includes a single array transistor 24 and a single capacitor 26. A given storage cell 22 of the memory array 12 may be accessed by activating a particular bit line and word line. As the storage cells 22 of the memory array 12 are arranged in a grid, only one cell 22 will be accessed for a given combination of word line and bit line activation.

For example, in order to write a data bit into storage cell (0,1), word line 0 is activated by applying an appropriate voltage to that line, e.g., a logic high (such as 3.3V, 5V, 15V, etc.) or a logic low (such as 0V). The appropriate voltage on word line 0 will turn on each of the array transistors 24 connected to that line including the array transistor 24 of cell (0,1). A voltage may then be presented on bit line 1, which will charge the capacitor 26 of cell (0,1) to a desired level, e.g., a logic high or logic low consistent with the data bit. The voltage may be presented on bit line 1 (and/or any of the other bit lines) by way of a suitably connected data bus. When the voltage on word line 0 is removed, the array transistor 24 of cell (0,1) is biased off and the charge on the capacitor 26 of cell (0,1) is stored.

Reading a data bit from a particular storage cell 22, such as cell (0,1), is substantially similar to writing a data bit except that the voltage on bit line 1 is imposed by the capacitor 26 of the storage cell 22 rather than by the data bus. Typically, a single storage cell 22 is not written to or read from; rather, an entire word (series of data bits) is written into the memory array 12 or read from the memory array 12 by applying the appropriate voltage on a particular word line and either imposing or sensing voltage on each of the bit lines, e.g., bit lines 0, 1, 2, etc.

Turning to FIG. 1, the sense amplifier 16 is used to sense and amplify data retrieved from the respective memory arrays 12, 14 over respective sets of bit lines 30, 32. The first and second sets of isolation transistors 18, 20 are used to ensure that data from only one of the first and second memory arrays 12, 14 are delivered to the sense amplifier at a given time. For example, when the sense amplifier 16 is to receive voltages from the bit lines 30 of the first memory array 12, the first set of isolation transistors 18 are biased on to connect the bit lines 30 of the first memory array 12 to the sense amplifier 16. The second set of isolation transistors are biased off to isolate the bit lines 32 of the second memory array 14 from the sense amplifier 16. Conversely, when the sense amplifier 16 is to receive voltages from bit lines 32 of the second memory array 14, the first set of isolation transistors 18 are biased off to break the connection between the bit lines 30 of the first memory array 12 and the sense amplifier 16, and the second set of isolation transistors 20 are biased on to connect the bit lines 32 of the second memory array 14 to the sense amplifier 16.

It is desirable to quickly write data into the respective capacitors 26 of the storage cells 22 (FIG. 2) of the memory arrays 12, 14 and to achieve a high storage density (large number of storage cells per unit area). Unfortunately, the voltage rise time of a given capacitor 26 is adversely affected by the combined impedances between the sense amplifier 16 and that capacitor 26. By way of example, the combined impedances may include, among other things, the impedance of one of the isolation transistors and the impedance of the array transistor 24 associated with the given capacitor 26. The effects of the isolation transistors on the voltage rise time of the capacitors 16 have not hereto for been satisfactory.

In addition, storage density is adversely effected by the design and/or location of the first and second sets of isolation transistors 18, 20. Indeed, the isolation transistors must be disposed a sufficient distance away from the transistors of the sense amplifier 16 to satisfy the applicable fabrication design rules (which are process specific). For example, the transistors of the sense amplifier 16 are typically thin-film field effect transistors (FETs) and the transistors of the first and second sets of isolation transistors 18, 20 are typically thick-film FETs. Fabrication design rules typically require relatively large separation between thick-film and thin-film FETs. Thus, in order to satisfy the fabrication design rules, the separation between the isolation transistors and the sense amplifier transistors is relatively large and adversely affects the density of the memory 10. This problem is exacerbated when the memory arrays 12, 14 include millions of storage cells and, therefore, a large number of isolation transistors are employed.

Accordingly, there is a need in the art for new approach to isolating memory arrays from a shared sense amplifier that improves the speed at which data may be written to a given storage cell and/or that improves the density of the memory.

### SUMMARY OF THE INVENTION

In accordance with at least one aspect of the present invention, a memory includes: a memory array disposed in an isolated well of semiconductor material and has a plurality of storage cells, each storage cell being accessible via one of a plurality of bit lines; a set of isolation transistors disposed in the isolated well of semiconductor material, each transistor having one of a source and drain coupled to a respective one of the bit lines of the memory array; and a sense amplifier disposed in semiconductor material outside the isolated well of semiconductor material and being coupled to the other of the source and drain of the respective isolation transistors.

The isolation transistors may be field effect transistors, such as N-channel field effect transistors, and the isolated well of semiconductor material may be P material. The isolation transistors may be thick-film field effect transistors and the array transistors may be thick-film field effect transistors. The capacitors may be trench capacitors formed in the isolated well of semiconductor material.

In accordance with further aspects of the present invention, the memory may include: one or more further memory arrays disposed respective isolated wells of semiconductor material and each including a plurality of storage cells, each storage cell being accessible via one of a respective set of bit lines; and one or more further sets of isolation transistors, each set of isolation transistors being disposed in a respective one of the isolated wells of semiconductor material, each transistor having one of a source and drain coupled to a respective one of the bit lines of one of the sets of bit lines of one of the further memory arrays, wherein the sense amplifier is disposed in semiconductor material outside all of the isolated wells of semiconductor material and is coupled to the other of the source and drain of the respective isolation transistors of two or more of the further sets of isolation transistors.

In accordance with one or more further aspects of the present invention, the memory array may be disposed in a first isolated well of semiconductor material and the set of isolation transistors may be disposed in a second isolated well of semiconductor material. The sense amplifier, however, is disposed in semiconductor material outside the first and second isolated wells of semiconductor material.

Other aspects, features, advantages, etc. will become apparent to one skilled in the art in view of the description herein taken in conjunction with the accompanying drawings.

### BRIEF DESCRIPTION OF THE DRAWINGS

For the purposes of illustrating the invention, there are shown in the drawings forms that are presently preferred, it being understood, however, that the invention is not limited to the precise arrangements and/or instrumentalities shown.

FIG. 1 is a block diagram illustrating a conventional memory architecture of the prior art;

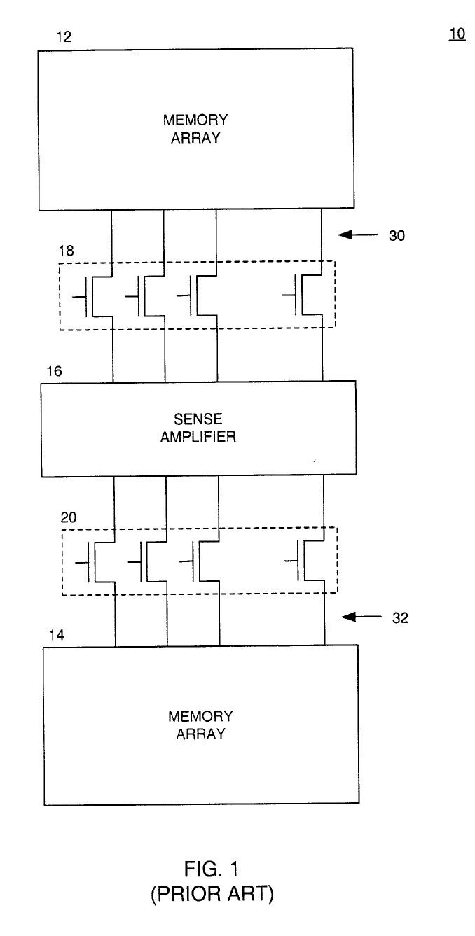

FIG. 2 is a schematic diagram illustrating a conventional circuit topology employed in forming memory arrays in accordance with the prior art;

FIG. 3 is a block diagram illustrating a memory architecture employing one or more aspects of the present invention;

FIG. 4 is a plan view illustrating a layout suitable for use in implementing a memory array in accordance with one or more aspects of the present invention;

FIG. 5 is a conceptual perspective diagram of a memory cell suitable for use with the present invention;

FIG. 6 is a sectional view through line 6-6 of FIG. 4; and

FIG. 7 is a timing diagram illustrating test results of a memory employing one or more aspects of the present invention.

### DETAILED DESCRIPTION

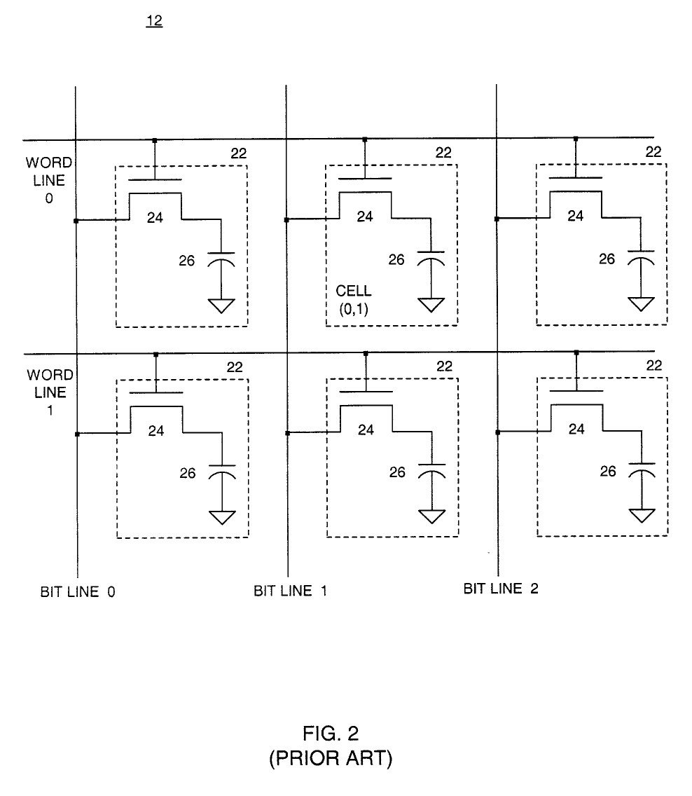

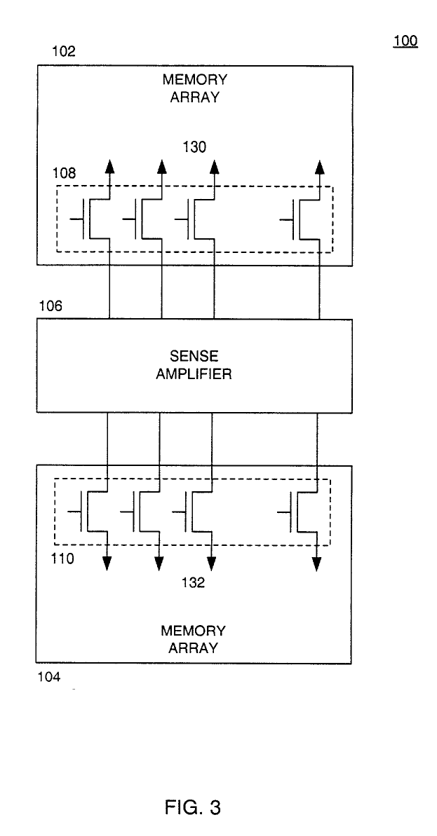

With reference to FIG. 3, a memory 100 in accordance with one or more aspects of the present invention includes a first memory array 102, a second memory array 104, and a sense amplifier 106. The first memory array 102 preferably includes a plurality of storage cells (not shown), such as those illustrated in FIG. 2, where each storage cell is accessible via one of a plurality of bit lines 130. The first memory array 102 preferably also includes a first set of isolation transistors 108 disposed in an integral fashion within the memory array 102.

The first set of isolation transistors 108 provides connections between the bit lines 130 and the sense amplifier 106. In particular, each transistor of the first set of isolation transistors 108 preferably includes one of a source and drain coupled to a respective one of the bit lines 130. An opposite one of the source and drain of each transistor of the first set of isolation transistors 108 is preferably coupled to the sense amplifier 106 such that voltages may be written to and read from the storage cells of the memory array 102.

The second memory array 104 preferably also includes a plurality of storage cells (not shown) and a second set of isolation transistors 110 disposed in an integral fashion within the memory array 104. The second set of isolation transistors 110 preferably provides interconnections between bit lines 132 of the second memory array 104 and the sense amplifier 106.

The first set of isolation transistors 108 are biased on when data are written to or read from the storage cells of the first memory array 102. On the other hand, the transistors of the second set of isolation transistors 110 are biased on when data are written to or read from the storage cells of the second memory array 104. Preferably, the isolation transistors contained within the first and/or second sets of isolation transistors 108, 110 are FETs, such as N-channel FETs.

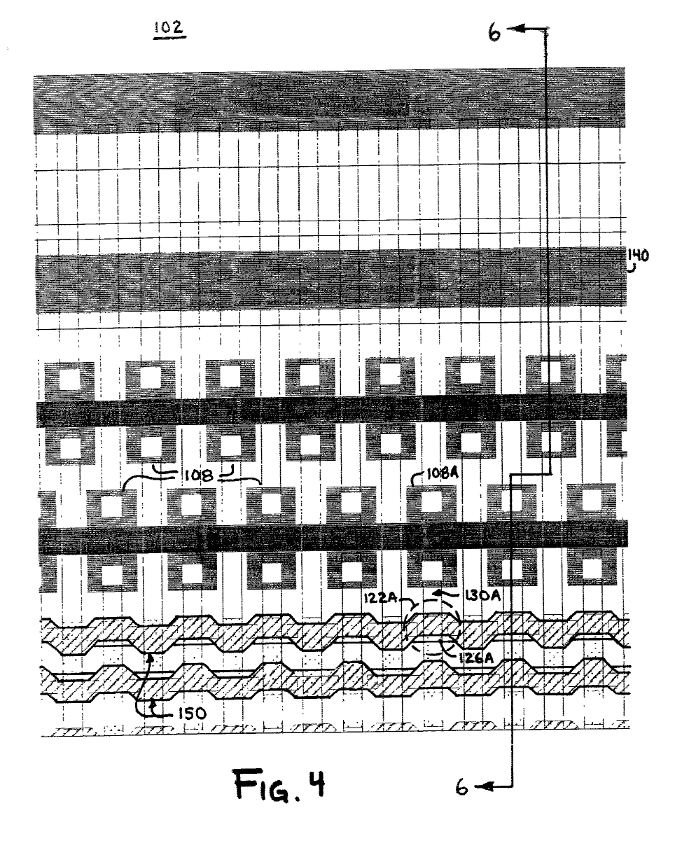

With reference to FIG. 4, a suitable layout of the first memory array 102 is shown in which the first set of isolation transistors 108 are disposed with a plurality of storage cells 122 within an isolation boundary 140 (described in more detail hereinbelow). More particularly, each storage cell, e.g., 122A, preferably includes a capacitor 126A that is coupled to one of a source and drain of one of the isolation transistors, such as transistor 108A, by way of a bit line 130A. An opposite one of the source and drain of the isolation transistor 108A leaves the first memory array 102 for connection to the sense amplifier 106. Respective sets of storage cells 122 are coupled together by way of respective word lines 150. It is noted the word lines 150 couple the gates of respective sets of array transistors together.

While FIG. 4 shows a suitable layout for the first memory array 102, it may also represent a suitable layout for the second memory array 104 and/or further memory arrays (not shown) without departing from the spirit and scope of the invention.

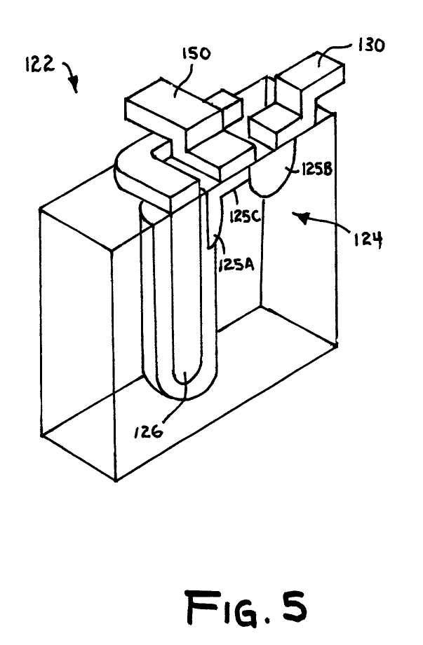

Any of the known structures for implementing the plurality of storage cells 122 may be employed in accordance with the present invention. For example, with reference to FIG. 5, a conceptual diagram of a suitable storage cell 122 is shown. The storage cell 122 includes a trench capacitor 126 and an array transistor 124 coupled to the trench capacitor 126 in order to permit access thereto. In particular, the array transistor 124 includes a drain 125A coupled to one side of the trench capacitor 126, a source 125B coupled to a bit line 130, and a gate coupled to a word line 150.

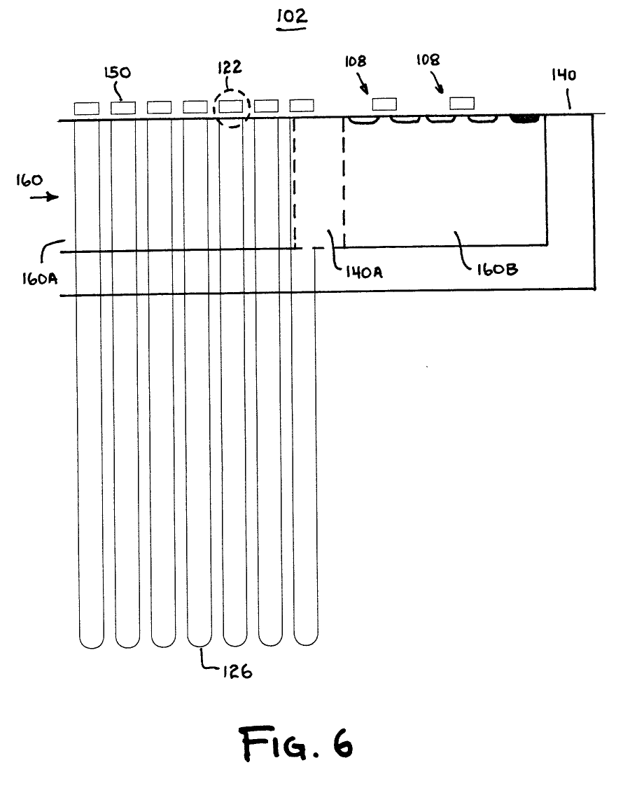

With reference to FIG. 6, which is a cross-sectional view of FIG. 4 taken through line 6-6, the storage cells 122 of the first memory array 102 are preferably disposed in an isolated well of semiconductor material 160 formed by the isolation boundary 140. For example, the isolated well of semiconductor material may be P material and the isolation boundary may be formed from N material (e.g., formed using an N well). The sense amplifier 106 is preferably disposed in semiconductor material outside the isolated well of semiconductor material 160. The first set of isolation transistors 108 are preferably disposed in the isolated well of semiconductor material 160.

While FIG. 6 shows a suitable structure for the first memory array 102, it may also represent a suitable structure for the second memory array 104 without departing from the spirit and scope of the invention.

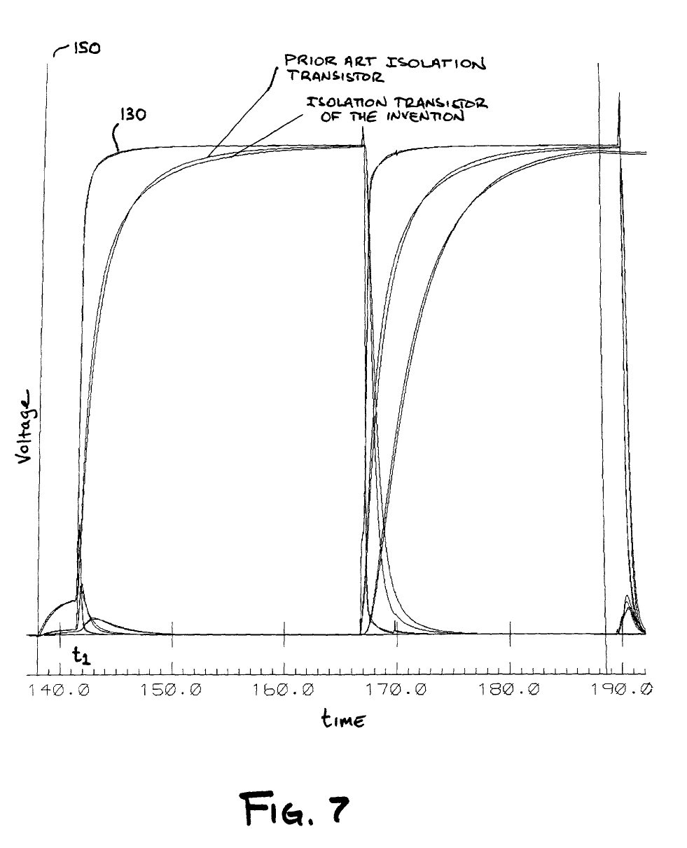

Advantageously, with reference to FIG. 7, the integrally disposed isolation transistors 108 have a positive effect on the speed at which the voltage rises on the capacitors 126 of the storage cells 122 during a data writing process. In particular, with a given word line 150 being high, and an associated bit line 130 transitioning high at time t1, the rate at which the capacitor 126 charges through an integrally disposed isolation transistor 108 in accordance with the invention is higher than that of a prior art isolation transistor disposed outside the memory array. The same effect may be achieved within the second memory array 104.

Preferably, the isolation transistors 108 (and/or isolation transistors 110) are thick-film FETs and the array transistors of the storage cells 122 are thick-film FETs. Advantageously, the integrally disposed isolation transistors 108 (and/or isolation transistors 110) may be disposed relatively close to the array transistors because most design rules permit two or more thick-film FETs to be disposed closer together than a thick-film FET and a thin-film FET (as would be the case when the isolation transistors are disposed outside the memory array 12 in accordance with the prior art).

It is noted that while two memory arrays 102, 104 coupled to one sense amplifier 106 are illustrated in FIG. 3, according to the invention, further memory arrays coupled to further sense amplifies may be employed in accordance with the present invention. It is preferred, however, that the memory arrays are implemented in accordance with the discussion above in conjunction with FIGS. 3-7.

Turning again to FIG. 6, when it is desirable to impose a negative back-bias voltage on the array transistors (i.e., imposing a slightly negative voltage, e.g., −0.5 V, between the source and the bulk material), then the isolated well of semiconductor material 160 is preferably divided into a first isolated well of semiconductor material 160A and a second isolated well of semiconductor material 160B separated by an isolation boundary 140A. In this way, the isolation transistors 108 (or the isolation transistors 110) need not be subject to the negative back-bias applied to the array transistors and the speed at which the capacitors 126 may be charged is not significantly impacted.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A memory, comprising:
a memory array disposed in an isolated well of semiconductor material and including a plurality of storage cells, each storage cell being accessible via one of a plurality of bit lines;
a set of isolation transistors disposed in the isolated well of semiconductor material, each transistor having one of a source and drain coupled to a respective one of the bit lines of the memory array; and
a sense amplifier disposed in semiconductor material outside the isolated well of semiconductor material and being coupled to the other of the source and drain of the respective isolation transistors.

2. The memory of claim 1, wherein the isolation transistors are field effect transistors.

3. The memory of claim 1, wherein the isolation transistors are N-channel field effect transistors and the isolated well of semiconductor material is P material.

4. The memory of claim 1, wherein each storage cell of the memory array includes an array transistor and a capacitor, a drain of the transistor being coupled to one side of the capacitor and a source of the transistor being coupled to one of the bit lines.

5. The memory of claim 4, wherein the isolation transistors are thick-film field effect transistors and the array transistors are thick-film field effect transistors.

6. The memory of claim 4, wherein the capacitors are trench capacitors formed in the isolated well of semiconductor material.

7. The memory of claim 1, further comprising:
one or more further memory arrays disposed in respective isolated wells of semiconductor material, each including a plurality of storage cells, each storage cell being accessible via one of a respective set of bit lines; and
one or more further sets of isolation transistors, each set of isolation transistors being disposed in a respective one of the isolated wells of semiconductor material, each transistor having one of a source and drain coupled to a respective one of the bit lines of one of the sets of bit lines of one of the further memory arrays,
wherein the sense amplifier is disposed in semiconductor material outside all of the isolated wells of semiconductor material and is coupled to the other of the source and drain of the respective isolation transistors of two or more of the further sets of isolation transistors.

8. The memory of claim 7, further comprising one or more further sense amplifiers, each sense amplifier being coupled to the other of the source and drain of the respective isolation transistors of two of the further sets of isolation transistors.

9. The memory of claim 7, wherein the isolation transistors are N-channel field effect transistors and the isolated wells of semiconductor material are P material.

10. The memory of claim 7, wherein each storage cell of each memory array includes an array transistor and a capacitor, a drain of the transistor being coupled to one side of the capacitor and a source of the transistor being coupled to one of the bit lines of a respective one of the sets of bit lines.

11. The memory of claim 10, wherein the isolation transistors are thick-film field effect transistors and the array transistors are thick-film field effect transistors.

12. The memory of claim 10, wherein the capacitors are trench capacitors formed in the respective isolated wells of semiconductor material.

13. A memory, comprising:
a memory array disposed in a first isolated well of semiconductor material and including a plurality of storage cells, each storage cell being accessible via one of a plurality of bit lines;
a set of isolation transistors disposed in a second isolated well of semiconductor material, each transistor having one of a source and drain coupled to a respective one of the bit lines of the memory array; and
a sense amplifier disposed in semiconductor material outside the first and second isolated wells of semiconductor material and being coupled to the other of the source and drain of the respective isolation transistors.

14. The memory of claim 13, wherein the isolation transistors are field effect transistors.

15. The memory of claim 13, wherein the isolation transistors are N-channel field effect transistors and the first and second isolated wells of semiconductor material are P material.

16. The memory of claim 13, wherein each storage cell of the memory array includes an array transistor and a capacitor, a drain of the transistor being coupled to one side of the capacitor and a source of the transistor being coupled to one of the bit lines.

17. The memory of claim 16, wherein the isolation transistors are thick-film field effect transistors and the array transistors are thick-film field effect transistors.

18. The memory of claim 16, wherein the capacitors are trench capacitors formed in the first isolated well of semiconductor material.

19. The memory of claim 13, further comprising:
one or more further memory arrays disposed in respective further isolated wells of semiconductor material, each including a plurality of storage cells, each storage cell being accessible via one of a respective set of bit lines; and
one or more further sets of isolation transistors, each set of isolation transistors being disposed in a respective still further isolated well of semiconductor material, each transistor having one of a source and drain coupled to a respective one of the bit lines of one of the sets of bit lines of one of the further memory arrays,
wherein the sense amplifier is disposed in semiconductor material outside all of the isolated wells of semiconductor material and is coupled to the other of the source and drain of the respective isolation transistors of two or more of the further sets of isolation transistors.

20. The memory of claim 19, further comprising one or more further sense amplifiers, each sense amplifier being coupled to the other of the source and drain of the respective isolation transistors of two of the further sets of isolation transistors.

21. The memory of claim 19, wherein the isolation transistors are N-channel field effect transistors and the isolated wells of semiconductor material are P material.

22. The memory of claim 19, wherein each storage cell of each memory array includes an array transistor and a capacitor, a drain of the transistor being coupled to one side of the capacitor and a source of the transistor being coupled to one of the bit lines of a respective one of the sets of bit lines.

23. The memory of claim 22, wherein the isolation transistors are thick-film field effect transistors and the array transistors are thick-film field effect transistors.

24. The memory of claim 22, wherein the capacitors are trench capacitors formed in the respective isolated wells of semiconductor material.
